(19) United States
(12) Patent Application Publication
(10) Pub. No.: US 2012/0165198 A1
(43) Pub. Date: Jun. 28, 2012

(54) SUPERCONDUCTING ELECTRIC MOTOR

(75) Inventors: Ryoji Mizutani, Nagoya-shi (JP); Yoshimasa Ohashi, Kariya-shi (JP); Nobuo Okumura, Toyota-shi (JP); Kenji Ishida, Nagoya-shi (JP)

(73) Assignee: TOYOTA JIDOSHA KABUSHIKI KAISHA, Toyota-shi (JP)

(21) Appl. No.: 13/335,109

(22) Filed: Dec. 22, 2011

(30) Foreign Application Priority Data
Dec. 28, 2010 (JP) 2010-292501

(51) Int. Cl. H01L 39/02; H02K 9/00

(52) U.S. Cl. 505/163; 310/57

(57) ABSTRACT

A superconducting electric motor includes: a rotor that is rotatably arranged; and a stator that is arranged in a radial direction of the rotor so as to face the rotor. The stator has a plurality of superconducting coils that are wound at a radial end portion of a stator core and that are formed of a superconducting wire material. The superconducting electric motor includes a refrigerator that has at least one narrow tube that flows low-temperature refrigerant inside. The at least one narrow tube is in thermal contact with the stator core and at least one of the coils.

### INCORPORATION BY REFERENCE

The disclosure of Japanese Patent Application No. 2010-292501 filed on Dec. 28, 2010 including the specification, drawings and abstract is incorporated herein by reference in its entirety.

### BACKGROUND OF THE INVENTION

1. Field of the Invention

The invention relates to a superconducting electric motor and, more particularly, to a superconducting electric motor that includes a refrigerator having at least one narrow tube that flows low-temperature refrigerant inside.

2. Description of Related Art

In an existing art, a superconducting electric motor that includes a refrigerator is suggested. For example, Japanese Patent Application Publication No. 2010-178517 (JP-A-2010-178517) describes a superconducting electric motor apparatus that includes a superconducting electric motor, a cryogenic temperature generator and a casing. The superconducting electric motor includes a rotor and a stator. The rotor includes a rotatable rotary shaft and a plurality of permanent magnets arranged on the outer peripheral portion of the rotary shaft. The stator has three-phase superconducting coils that are wound around the teeth of a stator iron core. The cryogenic temperature generator has a refrigerator that generates cryogenic temperature at its cold head. There is provided a heat conductive portion having a high thermal conductivity. The heat conductive portion connects the cold head to the stator iron core of the stator of the superconducting electric motor so that heat is transferable. A cooling cylindrical portion of the heat conductive portion is cooled into a cryogenic condition, and is brought into thermal contact with the outer peripheral portion of the stator iron core to cool the stator iron core. The casing forms a vacuum insulation chamber that thermally insulates the superconducting coils. Therefore, even when heat is transferred to the superconducting coils or even when refrigeration output from the refrigerator does not catch up, the stator iron core keeps the superconducting coils in a low-temperature condition. In addition, FIG. 3 of JP-A-2010-178517 shows that a heat conductive material having a high thermal conductivity is provided between each of the teeth of the stator iron core and a corresponding one of the superconducting coils, and FIG. 4 of JP-A-2010-178517 shows that a heat conductive material is connected via a connecting portion to the heat conductive portion that surrounds the outer peripheral portion of the stator iron core. With the above configuration, the superconducting coils may possibly be cooled via the teeth cooled by the cryogenic temperature generator.

In addition, International Publication No. WO/2003/001127A1 describes a cool storage refrigerator. The cool storage refrigerator includes pressure control means, an expansion/compression unit and a cool storage unit. The pressure control means have a compressor, a high-pressure selector valve and a low-pressure selector valve. The expansion/compression unit has a room-temperature end portion and a low-temperature end portion. The cool storage unit has a room-temperature end portion and a low-temperature end portion. The cool storage refrigerator transfers heat to a target to be cooled. The cool storage refrigerator couples the low-temperature end portion of the expansion/compression unit to the low-temperature end portion of the cool storage unit, and has a passage of working gas, extending to the target to be cooled. In addition, a pulse tube refrigerator generally serves an important role as cooling means for cooling sensors and semiconductor devices.

As in the case of the superconducting electric motor described in JP-A-2010-178517, in an existing art, cold is transferred by various methods when the superconducting coils are cooled; however, when the solid heat conductive materials are used to cool the superconducting coils, the thermal conductivity of each heat conductive material is finite, so, when heat is transferred through the heat conductive materials having a finite length, there occurs a temperature difference proportional to the amount of heat transferred and, therefore, it is difficult to improve cooling efficiency. For this reason, there is room for improvement in terms of improving the cooing efficiency of the superconducting coils to early cool the superconducting coils to thereby early generate a stable superconducting condition. On the other hand, in order to ensure the cooling performance of a superconducting electric motor irrespective of the load of the superconducting electric motor, it is conceivable to execute control such that the refrigeration output of a refrigerator is increased with the load. However, even in this case, there occurs a delay in response of heat transfer from the output of the refrigerator to the superconducting coils during a high load or in a transitional motor operating state in which the load steeply increases, and the temperature of the superconducting coils increases, so there still exists the possibility that a superconducting condition collapses. For example, in the case where the wheels of a vehicle are driven by a superconducting electric motor, when the superconducting electric motor becomes overloaded or highly loaded because of sudden acceleration, or the like, of the vehicle, the temperature of the superconducting coils may increase, so it is desired to develop means for being able to stably obtain a superconducting condition.

International Publication No. WO/2003/001127A1 merely describes a cool storage refrigerator, and does not describe that the refrigerator is used to cool the superconducting coils of the superconducting electric motor.

### SUMMARY OF THE INVENTION

The invention efficiently cools superconducting coils of a superconducting electric motor to a desired cryogenic temperature, effectively generates a stable superconducting condition even during a high load or in a transitional motor operating state.

An aspect of the invention relates to a superconducting electric motor. The superconducting electric motor includes: a rotor that is rotatably arranged; a stator that is arranged in a radial direction of the rotor so as to face the rotor; and a refrigerator that has at least one narrow tube that flows low-temperature refrigerant inside, wherein the stator has a stator core and a plurality of superconducting coils that are wound at a radial end portion of the stator core and that are formed of a superconducting wire material, and the at least one narrow tube is in thermal contact with both the stator core and at least one of the superconducting coils.

In addition, in the superconducting electric motor according to the aspect of the invention, the stator core may have an annular back yoke, a plurality of teeth that radially protrude from a radial end portion of the back yoke, and slots, each of which is provided between two of the teeth that are adjacent in a circumferential direction of the stator, the superconducting coils may be respectively wound around the teeth, the at least one narrow tube may have an extended portion extending in an axial direction of the stator in a corresponding one of the slots, and the extended portion may be in thermal contact with the stator core and at least one of the superconducting coils.

In addition, in the superconducting electric motor according to the aspect of the invention, the stator core may have an annular back yoke, a plurality of teeth that radially protrude from a radial end portion of the back yoke, and slots, each of which is provided between two of the teeth that are adjacent in a circumferential direction of the stator, the superconducting coils may be respectively wound around the teeth, and the at least one narrow tube may be arranged so as to be in contact with a bottom of a corresponding one of the slots and at least one of the superconducting coils.

In addition, in the superconducting electric motor according to the aspect of the invention, the at least one narrow tube may be in thermal contact with at least one of the teeth.

In addition, in the superconducting electric motor according to the aspect of the invention, the stator core may have an annular back yoke, a plurality of teeth that radially protrude from a radial end portion of the back yoke, and slots, each of which is provided between two of the teeth that are adjacent in a circumferential direction of the stator, the superconducting coils may be respectively wound around the teeth, and the at least one narrow tube may be arranged so as not to be in contact with the back yoke and so as to be in thermal contact with at least one of the teeth and at least one of the superconducting coils in a corresponding one of the slots.

In addition, in the superconducting electric motor according to the aspect of the invention, the stator may be arranged on a radially outer side of the rotor so as to face the rotor, the stator core may have the annular back yoke, the plurality of teeth that radially protrude from an inner peripheral end portion of the back yoke, and the slots, each of which is provided between two of the teeth that are adjacent in the circumferential direction of the stator, the at least one narrow tube may have a meandering portion that serves as the extended portion extending in the axial direction of the stator in the corresponding one of the slots, and at least part of an outer peripheral edge of the meandering portion, directed radially outward of the stator, may be in contact with a bottom of the corresponding one of the slots.

In addition, in the superconducting electric motor according to the aspect of the invention, resin may be filled in at least one of the slots.

In addition, in the superconducting electric motor according to the aspect of the invention, the plurality of superconducting coils each may have two coil end portions that respectively protrude axially outward from both axial end surfaces of the stator core, and the at least one narrow tube may have a coil end facing portion that is arranged so as to face an axially outer end surface portion of at least one of the two coil end portions and that is in contact with the at least one of the two coil end portions.

With the superconducting electric motor according to the aspect of the invention, the at least one narrow tube that is provided for the refrigerator and that flows low-temperature refrigerant inside is in thermal contact with the stator core and at least one of the superconducting coils, so it is possible to efficiently cool the superconducting coils to a desired cryogenic temperature and effectively generate a stable superconducting condition even during a high load or in a transitional motor operating state.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is an axially cross-sectional view that shows a superconducting electric motor according to a first embodiment of the invention;

FIG. 2 is an enlarged cross-sectional view that is taken along the line II-II in FIG. 1;

FIG. 3 is a view that shows the basic configuration of a refrigerator used in the first embodiment in a state where all narrow tubes extend linearly;

FIG. 4 is a cross-sectional view that is taken along the line IV-IV in FIG. 3;

FIG. 5 is an axially cross-sectional view that shows a superconducting electric motor according to a comparative embodiment that departs from the aspect of the invention;

FIG. 6 is a cross-sectional view that is taken along the line VI-VI in FIG. 5;

FIG. 7 is a view that shows a superconducting electric motor according to a second embodiment of the invention and that corresponds to FIG. 2;

FIG. 8 is a view that shows a meandering portion of each narrow tube in a corresponding one of slots when viewed outward from a radially inner side of a stator in the second embodiment;

FIG. 9A is an enlarged view of portion IXA in FIG. 7 with partially omitted;

FIG. 9B is a view that shows an example in which each narrow tube is not in contact with a back yoke in the second embodiment and that corresponds to FIG. 9A;

FIG. 10 is a view that shows a superconducting electric motor according to a third embodiment of the invention and that corresponds to FIG. 8;

FIG. 11 is a view when FIG. 10 is viewed from the right side toward the left side;

FIG. 12 is a view that shows a superconducting electric motor according to a fourth embodiment of the invention and that corresponds to FIG. 2;

FIG. 13 is a view that shows a superconducting electric motor according to a fifth embodiment of the invention and that corresponds to FIG. 2; and

FIG. 14 is a view that shows a superconducting electric motor according to a sixth embodiment of the invention and that corresponds to the half of FIG. 2.

### DETAILED DESCRIPTION OF EMBODIMENTS

### First Embodiment

Hereinafter, an embodiment of the invention will be described in detail with reference to the accompanying drawings. In this description, specific shapes, materials, numeric values, directions, and the like, are only illustrative for easily understanding the aspect of the invention and may be modified appropriately to meet an application purpose, an object, specifications, and the like.

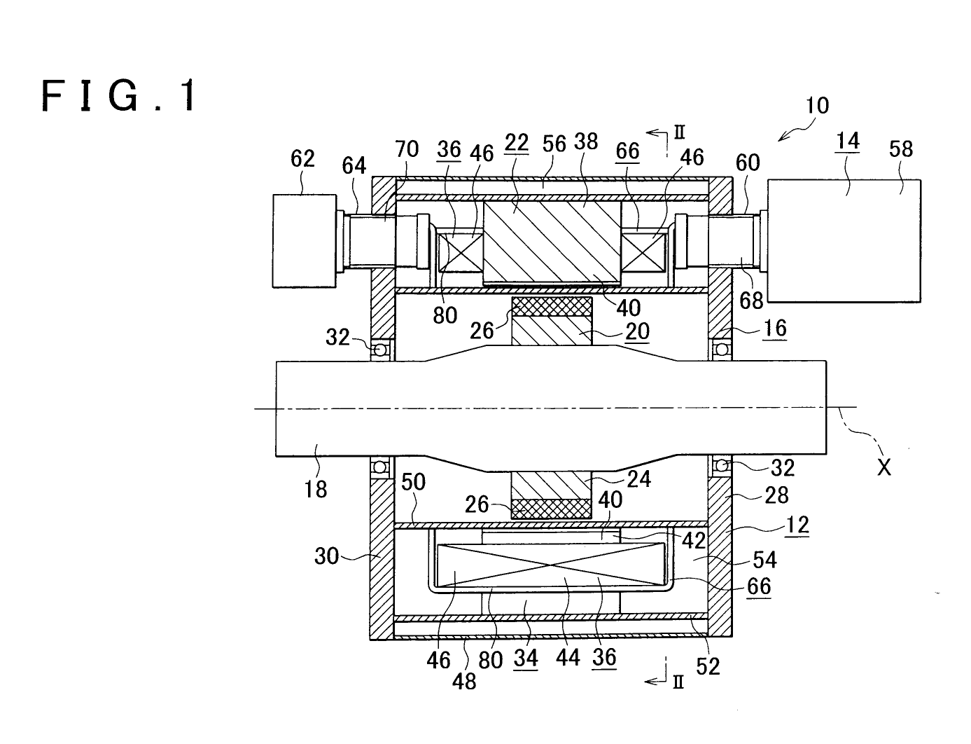

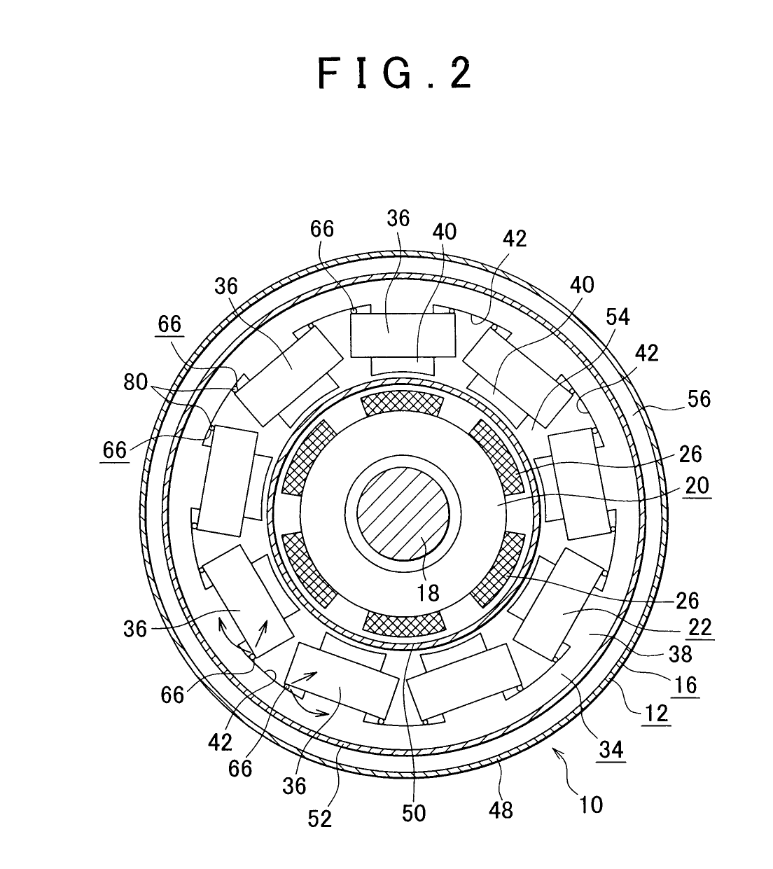

FIG. 1 to FIG. 4 show a superconducting electric motor according to a first embodiment of the invention. As shown in FIG. 1 and FIG. 2, the superconducting electric motor 10 includes a motor body 12 and a refrigerator 14. The refrigerator 14 is used to cool the motor body 12. The motor body 12 includes a motor case 16, a rotary shaft 18 and a rotor 20. The rotary shaft 18 is rotatably supported by the motor case 16. The rotor 20 is fixed to the outer side of the rotary shaft 18 inside the motor case 16 and is rotatably arranged. In addition, the motor body 12 includes a substantially cylindrical stator 22. The stator 22 is fixed to the inner peripheral surface of the motor case 16, and is arranged on the radially outer side of the rotor 20 so as to face the rotor 20. In addition, the refrigerator 14 is fixed to the motor case 16. Note that, in the following description, unless otherwise specified, a direction along the rotation central axis X of the rotary shaft 18 is termed axial direction, a radial direction perpendicular to the rotation central axis X is termed radial direction, and a direction along a circle about the rotation central axis X is termed circumferential direction.

The rotor 20 includes a cylindrical rotor core 24 and a plurality of permanent magnets 26. The rotor core 24 is, for example, formed so that flat rolled magnetic steel sheets are laminated and integrated by crimping, welding, or the like. The permanent magnets 26 are provided at equal intervals on the outer peripheral surface of the rotor core 24. That is, the plurality of (six in the example shown in FIG. 2) permanent magnets 26 are fixed to the outer peripheral surface of the rotor core 24 at equal intervals in the circumferential direction so that the permanent magnets 26 are exposed. The permanent magnets 26 are magnetized in the radial direction, and the magnetaized directions of the permanent magnets 26 are alternately varied in the circumferential direction. Therefore, north poles and south poles are alternately arranged on the outer peripheral surface of the rotor 20. However, the permanent magnets 26 of the rotor 20 may not be exposed on the outer peripheral surface, and may be embedded inside near the outer peripheral surface. The thus configured rotor 20 is fixed to the outer peripheral surface of the rotary shaft 18 made of round bar steel material, or the like.

The rotary shaft 18 is rotatably supported by bearings 32 at its both end portions. The bearings 32 are respectively fixed to disc-shaped end plates 28 and 30. The end plates 28 and 30 respectively constitute both end portions of the motor case 16. By so doing, as a revolving magnetic field is generated in the stator 22, the rotor 20 receives the influence of the revolving magnetic field to rotate.

The stator 22 includes a stator core 34 and coils 36. The stator core 34 has a substantially cylindrical shape and serves as a stator iron core. The coils 36 serve as superconducting coils. That is, the stator core 34 has an annular back yoke 38 and a plurality of (nine in the example shown in FIG. 2) teeth 40. The teeth 40 are provided at multiple portions of an inner peripheral end portion at equal intervals in the circumferential direction so as to protrude in the radial direction. The inner peripheral end portion is one radial end portion of the back yoke 38. In addition, the stator core 34 has a plurality of (nine in the example of the drawing) slots 42 that are provided at multiple portions at equal intervals in the circumferential direction. Each of the slots 42 is provided between two of the teeth 40, adjacent in the circumferential direction, at the inner peripheral portion of the back yoke 38. The stator core 34 may be, for example, formed in such a manner that a plurality of substantially annular flat rolled magnetic steel sheets are laminated in the axial direction and are integrally assembled by crimping, adhesion, welding, or the like. Instead, the stator core may be formed in such a manner that a plurality of split cores each having one tooth are arranged continuously in an annular shape and fastened by a cylindrical fastening member from the outer side. The split cores may be formed of dust core.

The plurality of coils 36 formed of a superconducting wire material are respectively wound around the plurality of teeth 40 of the stator core 34 by concentrated winding. Note that the plurality of coils 36 may be respectively wound around the teeth 40 by distributed winding. In addition, the superconducting wire material may have a circular cross-sectional shape or a rectangular cross-sectional shape. For example, the coils 36 may be formed in such a manner that a superconducting wire material that is a flat wire having a rectangular cross-sectional shape is wound in a flatwise manner. For example, the coils 36 may be formed in such a manner that a superconducting wire material is wound around each of the teeth 40 by solenoidal winding or pancake winding. In addition, the superconducting wire material may be suitably, for example, an yttrium series superconducting material or a bismuth series superconducting material. However, the superconducting material that constitutes the superconducting wire material is not limited to these materials; it may be another known superconducting material or a superconducting material that will be developed in the future and that exhibits a superconducting property at a higher temperature.

The superconducting wire material that constitutes each coil 36 may be covered with insulating coating. By so doing, when the superconducting wire material is wound so as to be in closely contact with one another to form each coil 36, electrical insulation is ensured among the turns of each coil 36. Instead, when the superconducting wire material is not covered with insulating coating, the superconducting wire material may be wound into a coil shape while placing insulating paper, insulating film, or the like, in between at the time of forming each coil 36 to thereby ensure electrical insulation among the turns of each coil 36.

Each coil 36 has in-slot portions 44 and two coil end portions 46. The in-slot portions 44 are respectively located in corresponding two of the plurality of slots 42 (FIG. 2) provided at multiple portions of the stator core 34. The two coil end portions 46 respectively protrude axially outward from both axial end surfaces of the stator core 34. Three of the coils 36, which place two coils 36 in between, are connected in series with one another to constitute any one of U, V and W phase coils. One ends of the phase coils are connected to one another at a neutral point (not shown), and the other ends of the phase coils are respectively connected to phase current introducing terminals (not shown).

In addition, the motor case 16 accommodates the rotor 20 and the stator 22. The motor case 16 has a cylindrical outer peripheral cylindrical portion 48 and the pair of end plates 28 and 30. The outer peripheral edge portions of the pair of end plates 28 and 30 are respectively airtightly connected to both axial end portions of the outer peripheral cylindrical portion 48. The outer peripheral cylindrical portion 48 and the end plates 28 and 30 are, for example, formed of a non-magnetic material, such as stainless steel. Note that the outer peripheral cylindrical portion 48 and the one-side end plate 28 (or 30) may be formed of an integral member.

An inner cylindrical member 50 and an intermediate cylindrical member 52 are provided inside the outer peripheral cylindrical portion 48 concentrically with the rotor 20. The inner cylindrical member 50 and the intermediate cylindrical member 52 each have a cylindrical shape. Both axial end portions of each of the inner cylindrical member 50 and intermediate cylindrical member 52 are respectively airtightly coupled to the inner surfaces of the end plates 28 and 30. The inner cylindrical member 50 is desirably formed of a non-metal material (for example, FRP, or the like) that does not interfere with passage of a magnetic field and that is electrically not conductive. More desirably, the inner cylindrical member 50 is formed of a material having a low thermal conductivity. Note that the inner cylindrical member 50 just needs to have the function of passing a magnetic field and the function of being able to retain vacuum at a space sealing portion, including the inner cylindrical member 50, as basic functions, and is not limited to the one using an electrically non-conductive material. For example, a non-magnetic material having a low electrical conductivity (for example, stainless steel, or the like) may also be used as the material that constitutes the inner cylindrical member 50. On the other hand, the intermediate cylindrical member 52 is desirably formed of a material having a low thermal conductivity (for example, FRP, or the like), and is more desirably formed of a non-magnetic material having a low thermal conductivity.

The inner cylindrical member 50 has an inside diameter that is slightly larger than the diameter of the outermost circumcircle of the rotor 20. A gap is formed between the inner cylindrical member 50 and the outer peripheral surface of the rotor 20. In addition, a first vacuum chamber 54 is provided between the inner cylindrical member 50 and the intermediate cylindrical member 52. The first vacuum chamber 54 is a cylindrical space. The stator 22 that includes the coils 36 are accommodated in the first vacuum chamber 54. The outer peripheral surface of the stator core 34 that constitutes the stator 22 is fixed to the inner peripheral surface of the intermediate cylindrical member 52.

The first vacuum chamber 54 is maintained in a vacuum condition in such a manner that, after the superconducting electric motor 10, including the refrigerator 14 described in detail later, is assembled, air is evacuated through an air vent hole (not shown) formed in at least any one of members, such as the end plates 28 and 30 and the outer peripheral cylindrical portion 48, that adjoin an external space and one or both of the first vacuum chamber 54 and a second vacuum chamber 56. In this way, the first vacuum chamber 54 is defined by the inner cylindrical member 50, which is not in contact with the coils 36 and the stator 22, and the intermediate cylindrical member 52 having a low thermal conductivity, and the inside of the first vacuum chamber 54 is evacuated. By so doing, it is possible to enhance heat insulation to the stator 22, including the coils 36, accommodated in the first vacuum chamber 54.

Furthermore, the second vacuum chamber 56 is formed between the intermediate cylindrical member 52 and the motor case 16. The second vacuum chamber 56 is formed of a cylindrical space. The second vacuum chamber 56, as well as the first vacuum chamber 54, is in a vacuum condition. A hole that provides fluid communication between the first vacuum chamber 54 and the second vacuum chamber 56 is desirably provided for the intermediate cylindrical member 52. By so doing, the stator 22, which includes the coils 36 and which is accommodated in the first vacuum chamber 54, is isolated from the outside of the motor additionally by the second vacuum chamber 56. Thus, it is possible to further enhance heat insulation effect to the stator 22 including the coils 36.

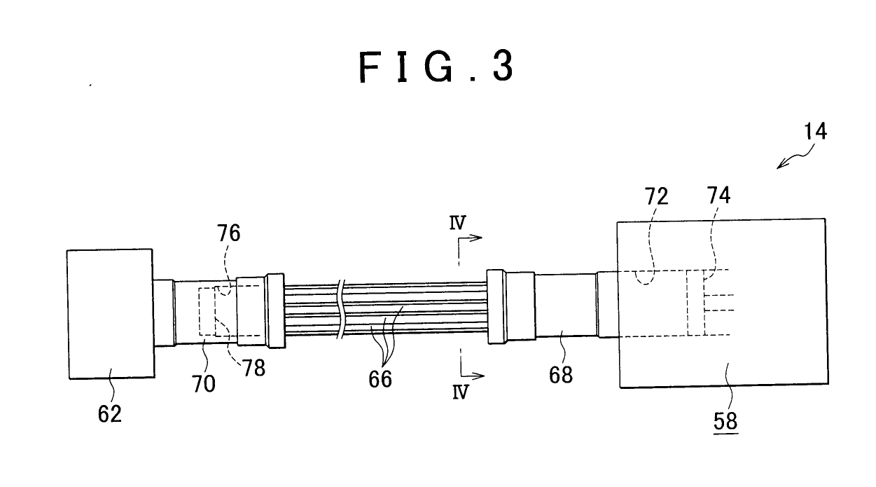

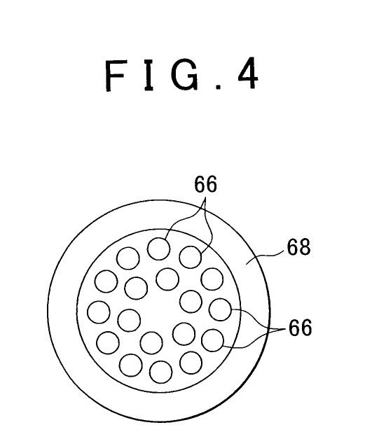

In addition, the refrigerator 14 is fixed to the motor body 12 that constitutes the superconducting electric motor 10. Next, the basic configuration of the refrigerator 14 will be described with reference to FIG. 3 and FIG. 4. FIG. 3 is a view that shows the basic configuration of the refrigerator 14 used in the present embodiment in a state where all narrow tubes 66 extend linearly. FIG. 4 is a cross-sectional view that is taken along the line IV-IV in FIG. 3. The refrigerator 14 is a free-piston Stirling cooler (FPSC). The refrigerator 14 has the plurality of narrow tubes 66 that are used to flow refrigerant gas. That is, the refrigerator 14 includes a pressure vibration source 58, a cool storage device 68, a phase controller 62, a second piston accommodating portion 70 and the plurality of narrow tubes 66. The pressure vibration source 58 is provided at one end of the refrigerator 14, and serves as a refrigerator drive source. The cool storage device 68 is called cold head, and one end portion of the cool storage device 68 is fixed to the pressure vibration source 58. The phase controller 62 is provided at the other end of the refrigerator 14. One end portion of the second piston accommodating portion 70 is fixed to the phase controller 62. The plurality of narrow tubes 66 are connected between the cool storage device 68 and the second piston accommodating portion 70. The plurality of narrow tubes 66 serve as a plurality of cooling portions, and are formed of a material having a high thermal conductivity. A cool storage medium (not shown) is provided inside the cool storage device 68. In addition, the cool storage device 68 and the second piston accommodating portion 70 have a heat insulation structure such that the outer sides of the cool storage device 68 and second piston accommodating portion 70 are covered with a heat insulation material.

The refrigerator 14 has a first piston 74. The first piston 74 linearly reciprocates in the cylinder 72 of the pressure vibration source 58, and serves as a drive piston. The space in the cylinder 72 is in fluid communication with the insides of the plurality of narrow tubes 66 via the inside of the cool storage device 68. In addition, the refrigerator 14 also has a second piston 78. The second piston 78 linearly reciprocates in the cylinder 76 of the second piston accommodating portion 70, and is called an expansion piston or a driven piston. The space in the cylinder 76 is in fluid communication with the insides of the plurality of narrow tubes 66 that serve as a low-temperature-side heat exchanging portion. Refrigerant gas (for example, helium gas) is filled in the internal space between the first piston 74 and the second piston 78, including the plurality of narrow tubes 66. That is, the narrow tubes 66 each are configured to flow low-temperature refrigerant gas inside.

In addition, the pressure vibration source 58 and the second piston accommodating portion 70 are arranged so as to face each other such that the directions in which the pistons 74 and 78 move are along the same straight line. The first piston 74 is, for example, connected to a mover of a linear motor, or the like, (not shown) that constitutes the pressure vibration source 58, and the linear motor is used to reciprocate the first piston 74 inside the cylinder 72. With the reciprocation of the first piston 74, the pressure of refrigerant gas varies within the cylinder 72 of the pressure vibration source 58. Owing to the pressure variation, the second piston 78 that is suspended by a spring formed of a coil spring, a leaf spring, or the like, (not shown) inside the phase controller 62 also dependently reciprocates. A phase difference between a pressure variation and a positional variation in refrigerant gas may be adjusted by the weight of the spring (not shown), the weight of the second piston 78 and a pressure variation resulting from the reciprocation of the first piston 74. In addition, a space that relieves a pressure variation resulting from the reciprocation of the second piston 78 is provided inside the phase controller 62. By so doing, the space is in fluid communication with the inside of the cylinder 76, in which the second piston 78 is arranged, to thereby make it possible to adjust the phase difference between the pressure variation and positional variation of refrigerant gas.

With the reciprocation of the first piston 74, refrigerant gas adiabatically expands and is cooled at a portion of the second piston accommodating portion 70 near the end portions of the narrow tubes 66, so refrigerant gas flowing through the insides of the narrow tubes 66 is also cooled. In this way, compression and expansion of refrigerant gas are repeated between the first piston 74 and the second piston 78 to cool the narrow tubes 66 through which refrigerant gas flows.

The refrigerator 14 has cooling performance such that the coils 36 made of a superconducting wire material may be cooled to a desired cryogenic temperature (for example, about 70 K.) at which the coils 36 exhibit a superconducting property. The cooling temperature of the refrigerator 14 may be adjusted by controlling the stroke of the first piston 74. Therefore, the stroke of the first piston 74 is controlled by a control unit (not shown). The control unit may be configured to control the cooling temperature of the refrigerator 14 according to a load of the superconducting electric motor 10 (FIG. 1). For example, the cooling temperature may be decreased with an increase in the load of the superconducting electric motor 10. When the superconducting electric motor 10 is mounted on an electromotive vehicle, such as an electric vehicle, as a driving source for propelling the vehicle, the refrigerator 14 is desirably smaller and lighter because of a limited installation space and a reduction in vehicle weight. When the FPSC is used as the refrigerator 14 as described above, the refrigerator 14 may be reduced in size and weight.

In the present embodiment, the refrigerator 14 having such a basic configuration is fixed to the motor body 12 (FIG. 1). That is, as shown in FIG. 1, in the superconducting electric motor 10, a cylindrical first bracket 60 adjacent to the pressure vibration source 58 that constitutes the refrigerator 14 is fixed to the end plate 28 located at one axial end, and a cylindrical second bracket 64 adjacent to the phase controller 62 that constitutes the refrigerator 14 is fixed to the end plate 30 located at the other axial end. Then, the pressure vibration source 58 and the second piston accommodating portion 70 are arranged along the same straight line parallel to the rotation axis X of the rotary shaft 18, and are arranged on both axial sides of the motor body 12. In addition, one end portion of the cool storage device 68 and one end portion of the second piston accommodating portion 70 respectively protrude into the first vacuum chamber 54 via the inside of the first bracket 60 and the inside of the second bracket 64.

In addition, as shown in FIG. 2, the longitudinal center portions of the plurality of narrow tubes 66, which serve as the low-temperature-side heat exchanging portion, are arranged two by two in each of the slots 42 that constitute the stator core 34. In FIG. 2, a plurality of arrows are shown on the stator 22, and each arrow indicates the direction in which cold is transferred from a corresponding one of the narrow tubes 66. In this way, cold is transferred from each narrow tube 66 to both a corresponding one of the coils 36 and the stator core 34 via the contact portions with the narrow tube 66. In this way, each of the plurality of narrow tubes 66 is configured so that the center portion is arranged in a corresponding one of the slots 42, so a part or whole of the plurality of narrow tubes 66 are formed such that the center portion is bent into a substantially crank shape, or the like.

As described above, the pressure vibration source 58 and the second piston accommodating portion 70 are arranged on both axial sides of the motor body 12. However, the present embodiment is not limited to this configuration. The pressure vibration source 58 and the second piston accommodating portion 70 are provided on only the one-side end plate 28 (or 30) of the pair of end plates 28 and 30 at positions different in the circumferential direction from each other, such as positions at opposite sides in the diametrical direction. The pressure vibration source 58 and the second piston accommodating portion 70 may be provided at positions different in the circumferential direction from each other, such as positions at opposite sides in the diametrical direction, that is, positions that are symmetrical with respect to the rotary shaft 18, on both axial sides of the motor body 12.

In addition, each narrow tube 66 has a straight portion 80 at a portion that includes the center portion arranged in a corresponding one of the slots 42. The straight portion 80 serves as an extended portion extending in the axial direction of the stator 22. Then, as shown in FIG. 2, each straight portion 80 is in contact with the bottom surface of a corresponding one of the slots 42 on the inner peripheral surface of the back yoke 38 and the radially outer end portion of the in-slot portion 44 (FIG. 1) that constitutes the coil 36 so as to be interposed therebetween. That is, the straight portion 80 of each narrow tube 66 is arranged between the bottom of the slot 42 and the coil 36 in a corresponding one of the slots 42 so as to be in contact with both the bottom of the slot 42 and the coil 36, and is in thermal contact with both the stator core 34 and the coil 36. With the above configuration, the narrow tubes 66 of which the number is twice the number of the slots 42 of the stator core 34 are provided. That is, the low-temperature-side heat exchanging portion is formed of the narrow tubes 66 of at least the same number as the number of the slots 42 of the stator core 34. In addition, each of the plurality of narrow tubes 66 is arranged parallel to the rotary shaft 18 in a corresponding one of the slots 42, and is in thermal contact with both the stator core 34 and a corresponding one of the coils 36 so as to cool the stator core 34 and the corresponding one of the coils 36. Note that the “thermal contact” in this specification and the appended claims includes not only direct contact between members that mutually transfer heat but also contact via a member having a thermal conductivity.

With the above configuration, a high-temperature-side heat exchanging portion is formed of an end portion of the second piston accommodating portion 70, arranged outside of the motor case 16. The above refrigerator 14 includes the pressure vibration source 58, the high-temperature-side heat exchanging portion, the cool storage device 68, the low-temperature-side heat exchanging portion and the second piston 78 (FIG. 3).

With the above superconducting electric motor 10, at least part of each of the narrow tubes 66 that constitute the refrigerator 14 and that flow low-temperature refrigerant gas inside is in thermal contact with both the stator core 34 and a corresponding one of the coils 36. Therefore, different from the configuration that a low-temperature solid heat transfer portion is brought into thermal contact with a corresponding one of the coils via the stator core to cool the corresponding one of the coils, it is possible to efficiently cool the coils 36 formed of a superconducting wire material to a desired cryogenic temperature. In addition, even during a high load of the superconducting electric motor 10 or in a transitional motor operating state of the superconducting electric motor 10, the narrow tubes 66 are brought into contact with the stator core 34 having a large thermal capacity. Therefore, the stator core 34 may be caused to function as a buffer to thereby effectively prevent a situation that cooling using the narrow tubes 66 cannot follow an increase in the temperature of the coils 36. By so doing, it is possible to stably continue cooling the coils 36. As a result, a stable superconducting condition may be effectively generated.

In addition, each narrow tube 66 has the axial straight portion 80 that serves as an extended portion extending in the axial direction of the stator 22 in a corresponding one of the slots 42, and each straight portion 80 is in contact with both the bottom of the slot 42 of the stator core 34 and a corresponding one of the coils 36 so as to be in thermal contact with both the stator core 34 and the corresponding one of the coils 36. Generally, a superconducting coil has an extremely poor heat conductivity as compared with a copper wire that constitutes the coil of an electric motor used at normal room temperatures, so it is difficult to uniformly cool the superconducting coil. In contrast to this, according to the above configured present embodiment, for example, in the coils, different from the case of a configuration that only the coil ends are cooled, the in-slot portions 44 of the coils 36 may be efficiently cooled, so the whole of the coils 36, which serve as superconducting coils, are easily cooled further uniformly. That is, the coils 36 may be cooled while reducing a biased temperature distribution among the whole of the coils 36.

Note that each narrow tube 66 has only one straight portion 80 that extends in the axial direction and that is provided in a corresponding one of the slots 42 in the above description. However, the present embodiment is not limited to such a configuration. It is also applicable that each narrow tube has two or more straight portions arranged in a corresponding one of the slots 42. In addition, it is also applicable that each narrow tube has a substantially U-shaped portion that is fitted around a corresponding one of the teeth 40 and the substantially U-shaped portion has straight portions that extend in the axial direction and that are respectively inserted in the adjacent slots 42.

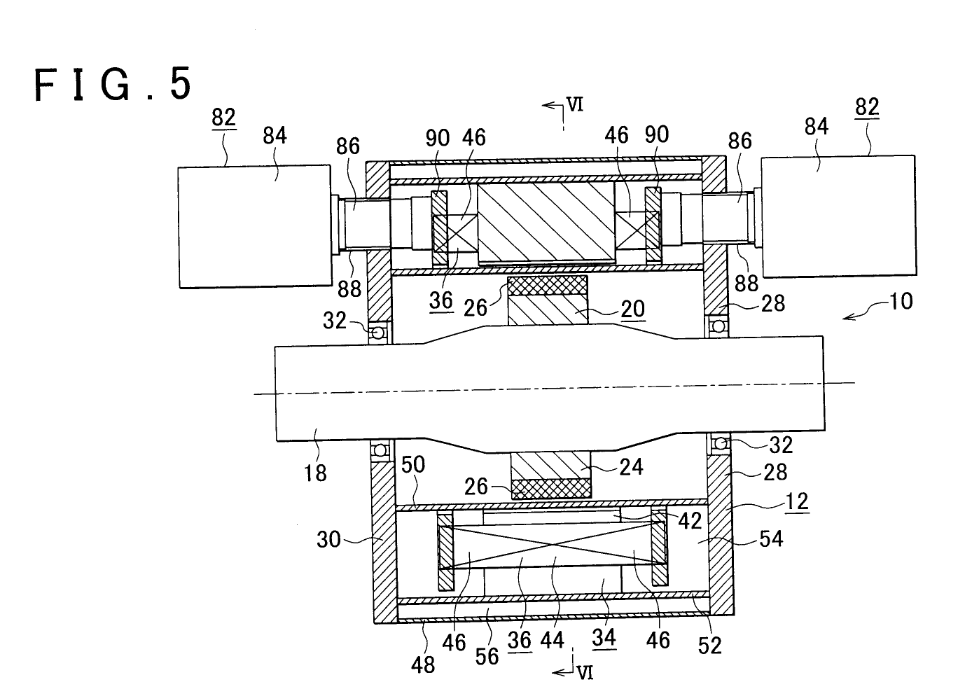

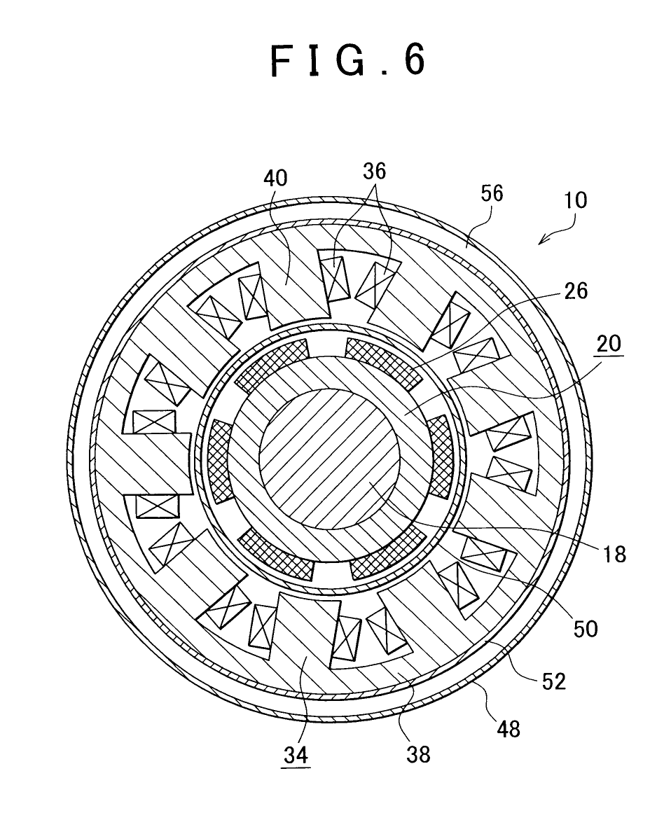

FIG. 5 is an axially cross-sectional view that shows a superconducting electric motor according to a comparative embodiment that departs from the aspect of the invention. FIG. 6 is a cross-sectional view that is taken along the line VI-VI in FIG. 5. The superconducting electric motor 10 according to the comparative embodiment shown in FIG. 5 and FIG. 6 differs from that of the structure of the present embodiment in that a pair of refrigerators 82 are provided on both sides of the motor body 12 instead of the refrigerator 14 (FIG. 1, and the like). That is, different from the refrigerator 14, each refrigerator 82 is an FPSC with no narrow tube that is used to flow refrigerant, and includes a gas compressor 84 that serves as a pressure vibration source and a cool storage device 86 that serves as a cooling portion connected to the gas compressor 84. In addition, the distal end portion of each cool storage device 86 is in contact with a disc-shaped heat transfer member 90 through the inside of a cylindrical bracket 88 fixed to the end plate 28 or 30. One-side surface of each heat transfer member 90 is in contact with the axially outer end portions of the coil end portions 46.

Each refrigerator 82 cools the coils 36 via the cool storage device 86 and the heat transfer member 90 in such a manner that a piston (not shown) reciprocates in a cylinder (not shown) provided inside the gas compressor 84 to repeatedly compress and expand refrigerant gas. With the above configuration as well, the coils 36 may be cooled; however, there is room for improvement in terms of easily cooling the whole of the coils 36 uniformly. In addition, each heat transfer member 90 transfers heat to a target to be cooled only using solid matter, which is different from the configuration that the narrow tubes that flow refrigerant inside are used, so there is room for improvement in terms of cooling the plurality of coils 36 uniformly. According to the above present embodiment, any of these points that should be improved may be improved.

Note that, in the above description, the refrigerator 14 is a passive refrigerator in which the second piston 78 is dependently displaced with a displacement of the first piston 74. However, a refrigerator may be provided with a second driving source, such as a linear motor, that forcibly displaces the second piston 78 at the side of the phase controller 62 so that, when the first piston 74 is reciprocally displaced, the second piston 78 is displaced at a phase shifted about 90 to 120 degrees from the phase of a cycle of the reciprocal displacement of the first piston 74. In this case, an active refrigerator is configured, and further energy saving may be achieved.

In addition, a refrigerator, other than an FPSC, may be used as the refrigerator 14. For example, when there is a small limitation on the installation space and weight of a refrigerator, such as when the superconducting electric motor 10 is used as a power source for a large-sized mobile unit, such as an electric train and a ship, or when a power source for a machine of which the installation site is fixed, a large and heavy refrigerator may be used as long as the refrigerator has a plurality of narrow tubes and has cooling performance such that a target to be cooled may be cooled to a cryogenic temperature (for example, about 70 K.).

In addition, a Stirling pulse tube refrigerator, a GM refrigerator, or the like, each having narrow tubes, may be used as the refrigerator. For example, in the pulse tube refrigerator, instead of the second piston accommodating portion 70, a pulse tube connected between the narrow tubes 66 and the phase controller 62 is used. No piston is provided inside the pulse tube. In the pulse tube refrigerator, the structure of vibrating pressure by opening and closing a valve may be used as the pressure vibration source 58. In addition, for the GM refrigerator, a rotary compressor or the structure of vibrating pressure by opening and closing a valve may be used in the FPSC refrigerator as the pressure vibration source 58. In addition, in this structure, the phase controller 62 is omitted and a displacer that serves as an expansion piston is reciprocally displaceably provided for the expansion/compression unit connected to the end portions of the narrow tubes 66, which are opposite to the pressure vibration source 58. The displacer is, for example, reciprocated by a motor, such as a stepping motor, during operation of the refrigerator. In this way, according to the aspect of the invention, various types of refrigerators may be used as the refrigerator as long as the refrigerators have narrow tubes that flow refrigerant inside.

### Second Embodiment

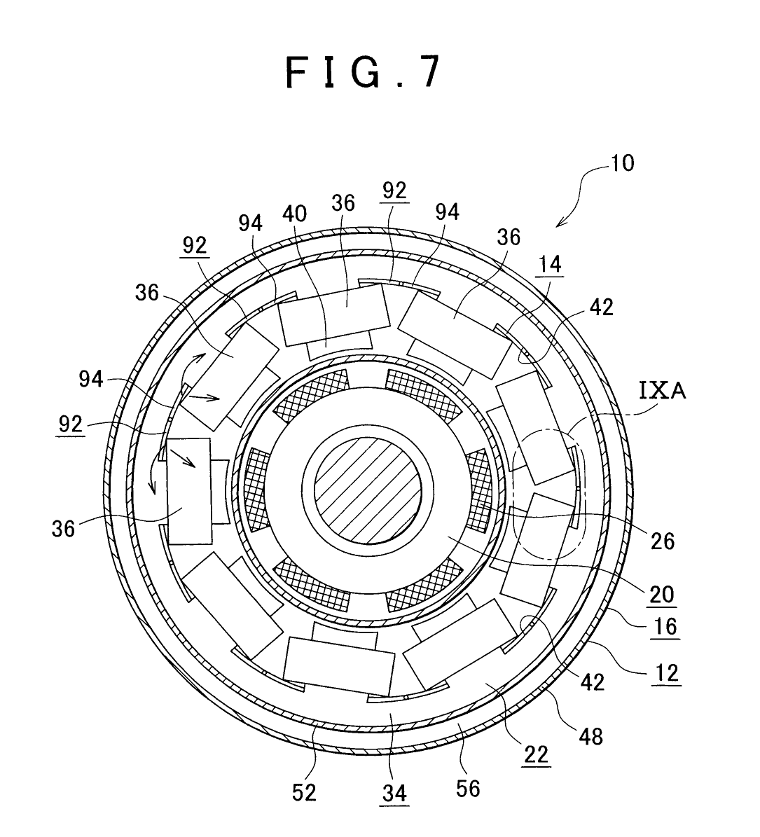

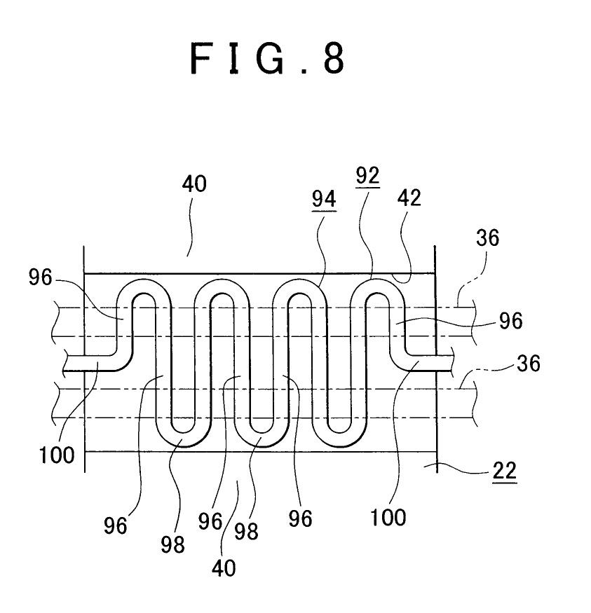

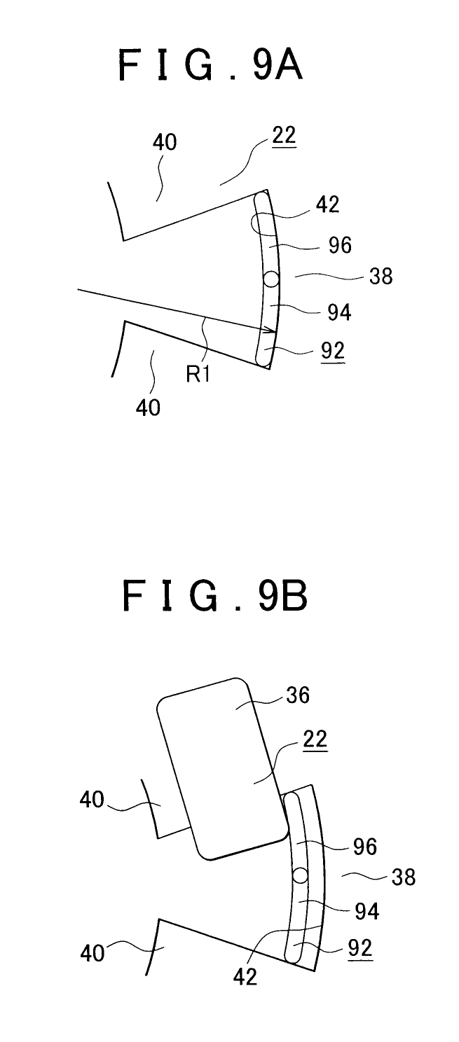

FIG. 7 is a view that shows a superconducting electric motor according to a second embodiment of the invention and that corresponds to FIG. 2. FIG. 8 is a view that shows a meandering portion of each narrow tube in a corresponding one of slots when viewed outward from a radially inner side of a stator in the second embodiment. FIG. 9A is an enlarged view of portion IXA in FIG. 7 with partially omitted.

The superconducting electric motor 10 according to the present embodiment differs from the first embodiment in that each of the plurality of narrow tubes does not have a straight portion extending over the entire length in the axial direction in a corresponding one of the slots 42. Instead, in the present embodiment, each of the plurality of narrow tubes 92 has a meandering portion 94 having a meander shape at its center portion arranged in a corresponding one of the slots 42. The meandering portion 94 serves as an extended portion extending in the axial direction of the stator 22. As shown in FIG. 8, each meandering portion 94 flows refrigerant gas inside, and has a plurality of circumferential portions 96 and substantially U-shaped coupling portions 98. The plurality of circumferential portions 96 extend in the circumferential direction (vertical direction in FIG. 8) of the stator 22. The coupling portions 98 each couple the end portions of the adjacent circumferential portions 96. Each meandering portion 126 extends in the axial direction (horizontal direction in FIG. 8) of the stator 22 as a whole. In addition, in each meandering portion 94, straight portions 100 that extend in the axial direction of the stator 22 are respectively coupled to the end portions of the circumferential portions 96 located at both axial ends of the slot 42. One end of one of the straight portions 100 (right side in FIG. 8) is connected to the cool storage device 68 (FIG. 1), and one end of the other one of the straight portions 100 (left side in FIG. 8) is connected to the second piston accommodating portion 70 (FIG. 1).

As shown in FIG. 9A, in the meandering portion 94 arranged in each slot 42, the outer peripheral edge (right end edge in FIG. 9A) in the radial direction of the stator 22 is in contact with the bottom of the slot 42. In addition, as shown in FIG. 8, in each circumferential portion 96 of each meandering portion 94, both end portions in the circumferential direction of the stator 22 are respectively in contact with the outer end portions of the circumferentially adjacent two coils 36 in the radial direction of the stator 22. That is, each narrow tube 66 is interposed between the stator core 34 and the end portions of the two coils 36 and is in thermal contact with both the stator core 34 and the end portions of the two coils 36. In the example of FIG. 8, both end portions of each circumferential portion 96 of each meandering portion 94 are respectively in contact with the coils 36.

In addition, as shown in FIG. 9A, each meandering portion 94 is curved in a substantially circular arc shape so that each circumferential portion 96 is aligned along the bottom of the slot 42, having a circular arc cross-sectional shape, when viewed in the axial direction of the stator 22 and is pressed against the bottom. For example, in a free state of each meandering portion 94, that is, a state where each meandering portion 94 is removed from the slot 42, the radius of curvature of the circular arc of the circular arc-shaped portion, which includes the circumferential portion 96 and which faces the bottom of the slot 42, may be larger than the radius of curvature R1 of the circular arc shape of the bottom of the slot 42. That is, in each meandering portion 94, the outer peripheral edge of the meandering portion 94, which is directed radially outward of the stator 22, is curved in a circular arc shape, and a part or whole of the outer end circle of the meandering portion 94 is brought into contact with the bottom of the slot 42 along the circumferential direction. Furthermore, the diameter of the outer peripheral edge in the free state of each meandering portion 94 is larger than the diameter of the circular arc cross-sectional shape of the bottom of the slot 42. With the above configuration, the contact pressure between the bottom of the slot 42 and the meandering portion 94 increases, so heat transport, that is, the efficiency of transfer of cold, is improved.

In the case of the above present embodiment as well, the coils 36 formed of a superconducting wire material are efficiently cooled to a desired cryogenic temperature, a stable superconducting condition may be effectively generated even during a high load or in a transitional motor operating state.

In addition, each narrow tube 92 has the meandering portion 94 that serves as an extended portion extending in the axial direction of the stator 22 in a corresponding one of the slots 42, and each meandering portion 94 is in contact with both the bottom of the slot 42 of the stator core 34 and the coils 36 so as to be in thermal contact with both the stator core 34 and the coils 36. Therefore, different from the configuration that only the coil ends are cooled, the entire portion of each coil 36 is easily cooled further uniformly. That is, the coils 36 may be cooled while reducing a biased temperature distribution among the whole of the coils 36. In addition, as indicated by the arrows in FIG. 7, cold may be transferred from each meandering portion 94 to corresponding two of the coils 36 and the stator core 34. In the above present embodiment, the number of the narrow tubes 92 of the refrigerator 14 may be equal to the number of the slots 42. With the configuration that cold is transferred by the meandering portions 94 to the stator core 34 and the coils 36, the shape of each meandering portion 94 is appropriately changed to adjust the degree of distribution of cooling between the stator core 34 and the coils 36 to make it easy to adjust a period of time from when the refrigerator 14 starts operating to when the refrigerator 14 enters a superconducting condition. Thus, it is possible to effectively prevent a collapse of the superconducting condition. The other configuration and function are the same as those of the first embodiment.

Note that, in the present embodiment, in the meandering portion 94 of each narrow tube 92, one or both of the both end portions in the circumferential direction of the stator 22 may be brought into thermal contact with corresponding one or two side surfaces of the teeth 40 facing the end portions of the meandering portion 94 in the circumferential direction. For example, an insulator (not shown) having an electrical insulation property is provided around each tooth 40, and each meandering portion 94 is brought into contact with a corresponding one of the teeth 40 via the insulator to thereby make it possible to bring each meandering portion 94 into thermal contact with the corresponding one of the teeth 40. For example, the insulator may be formed of a material having a high thermal conductivity, such as resin that contains a filler, such as silica, alumina and a nonmagnetic material having a high thermal conductivity. In this case, each narrow tube 92 is in thermal contact with the bottom of a corresponding one of the slots 42 of the stator core 34, corresponding two of the teeth 40 and corresponding two of the coils 36. Note that, in this case, portions of each meandering portion 94, facing the teeth 40 or the insulators, are formed as planar portions to bring the planar portions into plane contact with corresponding two of the teeth 40 or insulators to thereby make it possible to improve thermal conductivity. In addition, as in the case of another example shown in FIG. 9B, a gap is provided between the meandering portion 94 of each narrow tube 92 and the bottom of a corresponding one of the slots 42 to thereby make it possible to bring each narrow tube 92 into thermal contact with corresponding two of the teeth 40 and a corresponding one of the coils 36 without bringing each meandering portion 94 into contact with the bottom of the corresponding one of the slots 42. That is, each narrow tube 92 may be arranged in a corresponding one of the slots 42 such that the narrow tube 92 is not in contact with the back yoke 38 but the narrow tube 92 is in thermal contact with only both corresponding two of the teeth 40 and a corresponding one of the coils 36. In addition, even when each narrow tube has no meandering portion 94, it is also applicable that each narrow tube arranged in a corresponding one of the slots 42 has a U-shaped portion formed in a substantially U shape and the parallel straight portions on both sides of the U-shaped portion are brought into thermal contact with the circumferentially adjacent two teeth or insulators and two superconducting coils. In addition, in this case, in each slot 42, a gap is provided between each narrow tube and the back yoke to make it possible to bring each narrow tube not into contact with the back yoke.

### Third Embodiment

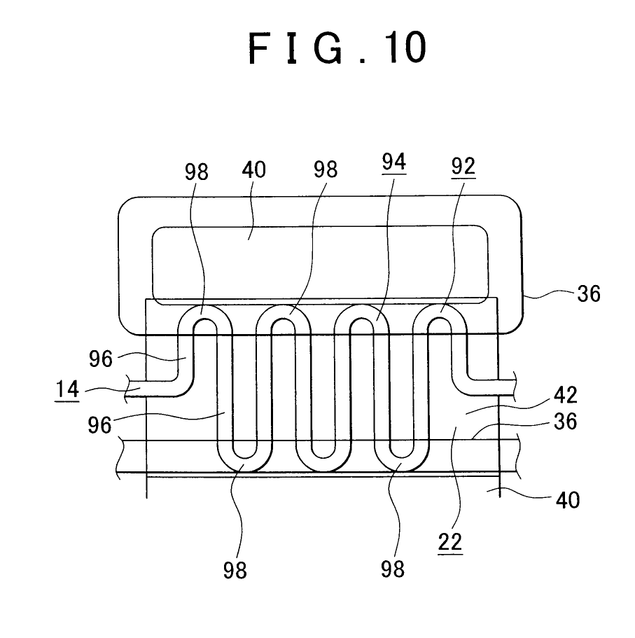

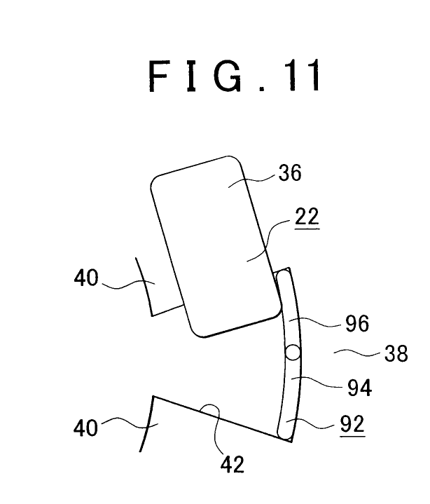

FIG. 10 is a view that shows a superconducting electric motor according to a third embodiment of the invention and that corresponds to FIG. 8. FIG. 11 is a view when FIG. 10 is viewed from the right side toward the left side. Note that, in FIG. 10, the overlap portion between the coil and the meandering portion 94 is shown as a see-through view.

In the second embodiment shown in FIG. 8, both end portions of each circumferential portion 96 of each meandering portion 94 in the circumferential direction of the stator 22 are respectively in contact with the end portions of two of the coils 36, adjacent in the circumferential direction. In contrast to this, in the present embodiment, in each meandering portion 94 provided in a corresponding one of the slots 42, the substantially U-shaped coupling portions 98 provided at both end portions in the circumferential direction of the stator 22 are sandwiched between the end portion of the coil 36 and the bottom of the slot 42 and are in contact with the end portion of the coil 36 and the stator core 34. The end portion of the coil 36 is brought into contact with the U-shaped coupling portions 98 in this way to increase the contact area between the coil 36 and the meandering portion 94 as compared with the second embodiment shown in FIG. 7 to FIG. 9B to thereby make it possible to improve cooling performance for cooling the coils 36. The way of bringing each meandering portion 94 into contact with the coil 36 and the contact portion are considered to adjust the degree of distribution of cooling between the stator core 34 and the coils 36 to make it easy to adjust a period of time from when the refrigerator 14 starts operating to when the refrigerator 14 enters a superconducting condition. Thus, it is possible to effectively prevent a collapse of the superconducting condition. The other configuration and function are the same as those of the second embodiment shown in FIG. 7 to FIG. 9B. Note that, in the present embodiment, in the meandering portion 94 of each narrow tube 92, one or both of the both end portions in the circumferential direction of the stator 22 may be brought into thermal contact with corresponding one or two side surfaces of the teeth 40 facing the end portions of the meandering portion 94 in the circumferential direction, as in the case of the second embodiment.

### Fourth Embodiment

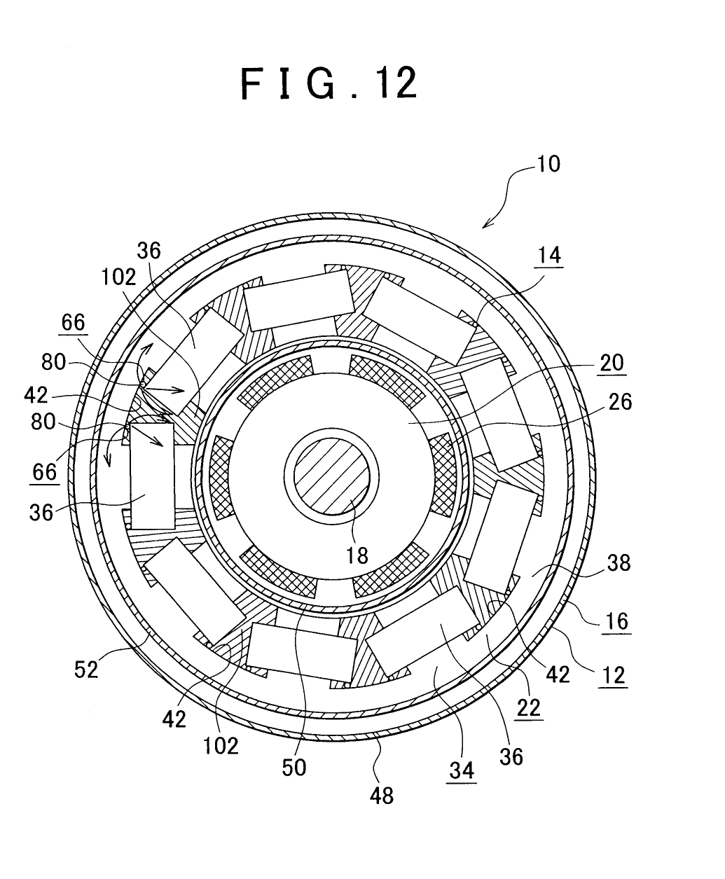

FIG. 12 is a view that shows a superconducting electric motor according to a fourth embodiment of the invention and that corresponds to FIG. 2. The present embodiment differs from the first embodiment shown in FIG. 1 to FIG. 4 in that resin portions 102 formed of resin filled in the slots 42 that constitute the stator core 34 are provided. Although the type of resin is not limited, the resin is desirably a high thermal conductivity resin having a high thermal conductivity, which contains a filler, such as silica, alumina and a nonmagnetic material having a high thermal conductivity. In addition, a portion, arranged in a corresponding one of the slots 42, of the straight portion 80 that constitutes each narrow tube 92 in a state of being molded in resin is in contact with both the bottom of the slot 42 and a corresponding one of the coils 36 so as to be interposed between the bottom of the slot 42 and the outer end portion of the coil 36 in the radial direction of the stator 22.

With the above configuration, an additional cooling path formed of the resin portion 102 is formed at a portion that is close to the radially inner side of the stator 22 and that is located apart from each of the narrow tubes 66 that constitute the refrigerator 14 in a corresponding one of the slots 42, so, in combination with an increase in the heat transfer area of the portion that transfers cold from the narrow tubes 66 to the coils 36 owing to the resin portions 102, a biased temperature distribution of the coils 36 is hard to occur. In addition, more desirably, an air layer between the coils 36 and the stator core 34 is eliminated by resin injection molding, or the like, that is, resin is filled into the entire space of each of the slots 42, to thereby make it possible to obtain further high advantageous effect of cooling performance. The other configuration and function are the same as those of the first embodiment shown in FIG. 1 to FIG. 4.

### Fifth Embodiment

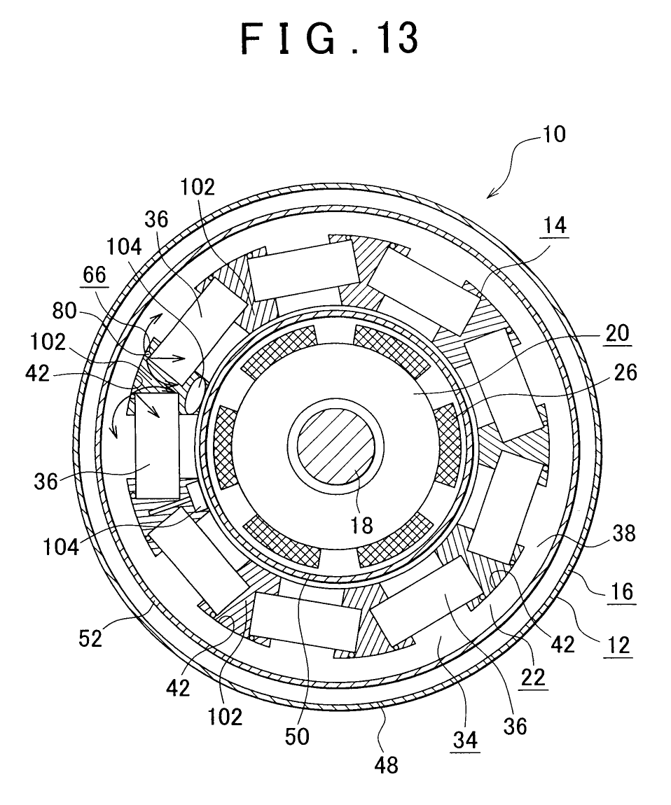

FIG. 13 is a view that shows a superconducting electric motor according to a fifth embodiment of the invention and that corresponds to FIG. 2. The present embodiment differs from the fourth embodiment shown in FIG. 12 in that at least part of the resin portions 102 provided in the corresponding slots 42 that constitute the stator core 34 have void portions 104. The shape of each void portion 104 is not limited. For example, as shown in FIG. 13, the void portion 104 having a substantially elliptical cross-sectional shape or a shape that couples a plurality of rectangular cross-sectional portions to each other, such that the void portion 104 axially penetrates through the resin portion 102, is provided in a corresponding one of the slots 42. However, the void portion may be formed in a shape that does not axially penetrate through the resin portion 102 in a corresponding one of the slots 42. In addition, in the example of the drawing, the void portion 104 is provided for only part of the resin portions 102 in the slots 42; instead, the void portion 104 may be provided for all the resin portions 102 in the slots 42.

With the above configuration, the void portion 104 is provided in at least part of the resin portions 102 that are provided so as to be filled in the corresponding slots 42 to make it easy to adjust a heat transfer path that transfers cold from the narrow tubes 66 to the coils 36, and heat transport to a redundant portion is prevented to improve cooling performance for cooling the coils 36. In addition, the thermal capacity of the resin portions 102 may be adjusted by the void portions 104 to thereby make it easy to adjust cooling performance. The other configuration and function are the same as those of the fourth embodiment shown in FIG. 12.

### Sixth Embodiment

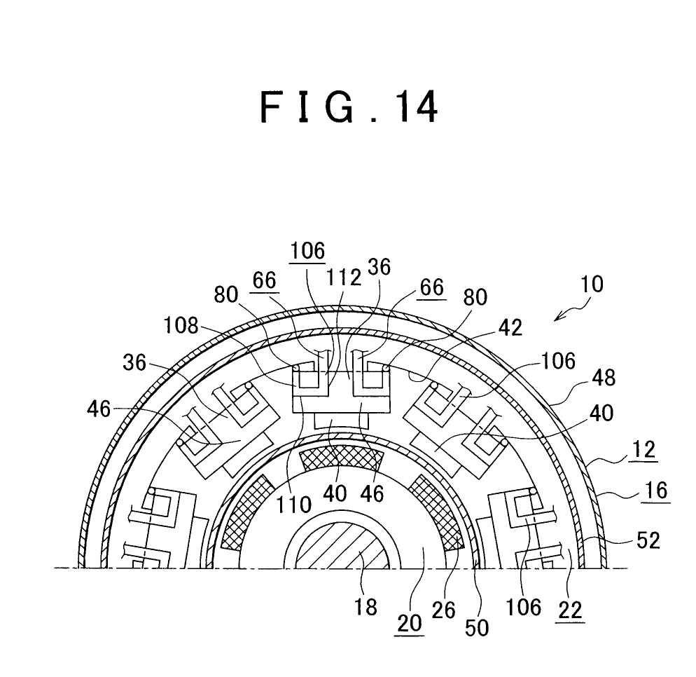

FIG. 14 is a view that shows a superconducting electric motor according to a sixth embodiment of the invention and that corresponds to the half of FIG. 2. The present embodiment differs from the first embodiment shown in FIG. 1 to FIG. 4 in that each narrow tube 66 having the straight portion 80 arranged in a corresponding one of the slots 42 that constitute the stator core 34 has coil end facing portions 106 at portions that protrude outward from the corresponding one of the slots 42. The coil end facing portions 106 are arranged so as to face the axially outer end surface portions of the coil end portions 46. In the example of the drawing, each coil end facing portion 106 of each narrow tube 66 has a first radial portion 108, a circumferential portion 110 and a second radial portion 112. The first radial portion 108 is bent radially inward of the stator 22 to extend in the radial direction along the axially outer end surface portion of the coil end portion 46. The circumferential portion 110 is coupled to the radially inner end portion of the first radial portion 108 and extends in the circumferential direction near the circumferential center of the corresponding tooth 40. The second radial portion 112 is coupled to the end portion of the circumferential portion 110, opposite to the first radial portion 108, and extends radially outward. Then, at least part of the first radial portion 108, circumferential portion 110 and second radial portion 112 is brought into contact with the axially outer side surface portion of the coil end portion 46 so as to be in thermal contact with the axially outer side surface portion of the coil end portion 46. That is, each narrow tube 66 is arranged so as to be in contact with the coil end portions 46 on both sides (both sides in the front-back direction of FIG. 14). With the above configuration, cooling performance for cooling the coils 36 may be further improved, and the whole of the coils 36 may be easily cooled further uniformly. That is, the coils 36 may be cooled while reducing a biased temperature distribution among the whole of the coils 36. Note that it may be configured such that each narrow tube is only brought into contact with the axially outer end portion of one of the pair of coil end portions 46. The other configuration and function are the same as those of the first embodiment shown in FIG. 1 to FIG. 4. Note that the structure of a portion that brings each narrow tube 66 into contact with the axially outer side surface portions of the coil end portions 46 is not limited to the structure having the illustrated shape; instead, various structures may be employed.

Note that, in the above embodiments, the aspect of the invention is applied to the inner rotor structure in which the stator is arranged on the radially outer side of the rotor so as to face the rotor. However, the aspect of the invention is not limited to this configuration. The aspect of the invention may be applied to an outer rotor structure in which the stator is arranged on the radially inner side of the rotor so as to face the rotor. In this case, the superconducting coils are wound at an outer peripheral end portion that is one radial end portion of the stator core.

1-10. (canceled)

11. A superconducting electric motor comprising:
a rotor that is rotatably arranged;
a stator that is arranged in a radial direction of the rotor so as to face the rotor; and
a refrigerator that has at least one narrow tube that flows low-temperature refrigerant inside, wherein
the stator has a stator core and a plurality of superconducting coils that are wound at a radial end portion of the stator core and that are formed of a superconducting wire material, and
the at least one narrow tube is in thermal contact with the stator core and at least one of the superconducting coils.

12. The superconducting electric motor according to claim 11, wherein
the stator core has an annular back yoke, a plurality of teeth that radially protrude from a radial end portion of the back yoke, and slots, each of which is provided between two of the teeth that are adjacent in a circumferential direction of the stator,
the superconducting coils are respectively wound around the teeth,
the at least one narrow tube has an extended portion extending in an axial direction of the stator in a corresponding one of the slots, and
the extended portion is in thermal contact with the stator core and at least one of the superconducting coils.

13. The superconducting electric motor according to claim 12, wherein
the extended portion is one of a straight portion and a meandering portion.

14. The superconducting electric motor according to claim 11, wherein
the stator core has an annular back yoke, a plurality of teeth that radially protrude from a radial end portion of the back yoke, and slots, each of which is provided between two of the teeth that are adjacent in a circumferential direction of the stator,
the superconducting coils are respectively wound around the teeth, and
the at least one narrow tube is arranged so as to be in contact with a bottom of a corresponding one of the slots and at least one of the superconducting coils.

15. The superconducting electric motor according to claim 14, wherein
the at least one narrow tube is in thermal contact with at least one of the teeth.

16. The superconducting electric motor according to claim 11, wherein
the stator core has an annular back yoke, a plurality of teeth that radially protrude from a radial end portion of the back yoke, and slots, each of which is provided between two of the teeth that are adjacent in a circumferential direction of the stator,
the superconducting coils are respectively wound around the teeth, and
the at least one narrow tube is arranged so as not to be in contact with the back yoke and so as to be in thermal contact with at least one of the teeth and at least one of the superconducting coils in a corresponding one of the slots.

17. The superconducting electric motor according to claim 12, wherein
the stator is arranged on a radially outer side of the rotor so as to face the rotor,
the stator core has the annular back yoke, the plurality of teeth that radially protrude from an inner peripheral end portion of the back yoke, and the slots, each of which is provided between two of the teeth that are adjacent in the circumferential direction of the stator,
the at least one narrow tube has a meandering portion that serves as the extended portion extending in the axial direction of the stator in the corresponding one of the slots, and
at least part of an outer peripheral edge of the meandering portion, directed radially outward of the stator, is in contact with a bottom of the corresponding one of the slots.

18. The superconducting electric motor according to claim 17, wherein
a radius of curvature of a circular arc of a circular arc portion of the meandering portion, facing the bottom of the corresponding one of the slots, is larger than a radius of curvature of a circular arc shape of the bottom of the corresponding one of the slots.

19. The superconducting electric motor according to claim 11, wherein
resin is filled in at least one of the slots.

20. The superconducting electric motor according to claim 11, wherein
the plurality of superconducting coils each has two coil end portions that respectively protrude axially outward from both axial end surfaces of the stator core, and
the at least one narrow tube has a coil end facing portion that is arranged so as to face an axially outer end surface portion of at least one of the two coil end portions and that is in contact with the at least one of the two coil end portions.
